(19) United States
(12) Patent Application Publication
(10) Pub. No.: US 2013/0197129 A1
(43) Pub. Date: Aug. 1, 2013

(54) LIQUID EPOXY RESIN COMPOSITION AND SEMICONDUCTOR DEVICE

(71) Applicant: SHIN-ETSU CHEMICAL CO., LTD., Tokyo (JP)

(72) Inventors: Hideki AKIBA, Annaka-shi (JP); Kazuaki SUMITA, Annaka-shi (JP); Yasuo KIMURA, Annaka-shi (JP); Shinsuke YAMAGUCHI, Annaka-shi (JP)

(73) Assignee: SHIN-ETSU CHEMICAL CO., LTD., Tokyo (JP)

(21) Appl. No.: 13/753,899

(22) Filed: Jan. 30, 2013

(30) Foreign Application Priority Data
Feb. 1, 2012 (JP) 2012-019421

(51) Int. Cl. H01L 23/29

(52) U.S. Cl. CPC H01L 23/295
USPC 523/433; 523/400; 523/455; 523/466

(57) ABSTRACT

Disclosed is a liquid epoxy resin composition containing: (A) a liquid epoxy resin comprising at least one liquid epoxy resin represented by the following general formula (1) or (2):

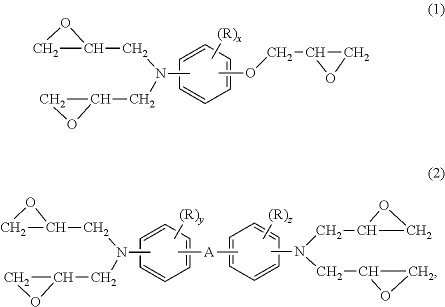

(B) a phenolic curing agent, (C) an accelerator in an amount of 0.01 to 10 parts by weight based on 100 parts by weight of component (A), and (D) an inorganic filler in an amount of 20 to 900 parts by weight based on 100 parts by weight of component (A).

### CROSS-REFERENCE TO RELATED APPLICATION

This non-provisional application claims priority under 35 U.S.C. §119(a) on Patent Application No. 2012-019421 filed in Japan on Feb. 1, 2012, the entire contents of which are hereby incorporated by reference.

### TECHNICAL FIELD

The present invention relates to a liquid epoxy resin composition for use in semiconductor sealing which is excellent in reliability and workability and which promises a simpler semiconductor device manufacturing process, and to a semiconductor device sealed with the epoxy resin composition.

### BACKGROUND ART

In recent years, there has been a marked trend toward an increasingly higher semiconductor chip density, attendant on reductions in size, thickness and weight of semiconductor packages. As a representative process for high-density mounting of semiconductor chips, the flip chip mounting has been practiced widely. A typical one of the flip chip mounting processes is the C4 (controlled collapse chip connection) process in which solder electrodes of a semiconductor chip and solder bumps or solder lands on a mounting substrate are joined directly to each other by solder. After joining, the gap between the semiconductor chip and the mounting substrate is sealed with an epoxy resin, for protection of the joints.

In the flip chip mounting based on the C4 process, resin sealing by a capillary flow method has conventionally been carried out. This procedure, however, involves many steps including (1) a solder wettability improving treatment by use of a flux, (2) joining by solder, (3) cleaning of the flux, (4) injection of a liquid sealant resin by capillarity, and (5) curing of the resin. It takes much time to carry out the resin injection. Thus, this procedure is low in productivity. Especially, attendant on the trend toward a finer pad size and a narrower pitch thereof, the conditions for cleaning away the flux have been worsened. As a result, there are many technical difficulties concerning the flux, such as poor wetting of sealant resin due to flux residue and a lowered semiconductor package reliability due to ionic impurities present in the flux residue.

As a countermeasure against these problems related to the capillary flow method, there has been proposed a non-flow process (U.S. Pat. No. 5,128,746) in which a sealant resin admixed with a flux ingredient is applied directly to a mounting substrate, a semiconductor chip provided with solder electrodes is mounted thereon, and joining with solder and sealing with the resin are simultaneously carried out by reflow. In addition, at present, a method for enhancing the productivity has been investigated. In this approach, by use of a flip chip bonder apparatus, a sealant resin having a fluxing capability is applied to a substrate, a semiconductor chip provided with solder electrodes is mounted thereon, and thermocompression bonding is conducted, so as to speedily and simultaneously achieve solder joining between the substrate and the semiconductor chip and curing of the sealant resin. This approach, however, has an augmented technical problem as to generation of voids in the sealant resin. One reason lies in that the resin curing is conducted through thermocompression bonding of the substrate and the semiconductor chip in a short time. Another reason lies in that the solder joining has come to be conducted at a higher temperature than in the past, attendant on the tendency toward the use of lead-free solder materials. Besides, in response to the recent trend toward a higher-density system of semiconductor packages, a structure (COC (Chip-On-Chip) structure) in which a semiconductor chip and a semiconductor chip are joined to each other may be adopted. In this case, the semiconductor chips are higher in thermal conductivity (lower in heat insulating property) than the glass-epoxy substrates used conventionally. Therefore, solder would be melted insufficiently and solder joint properties would be worsened, unless the solder joining temperature is raised further. Consequently, it becomes very important to cope with the void generation problem by lowering the volatility of the resin ingredients.

In addition, the recent trend toward lead-free solders is accompanied by the need to compensate for the lowered solder adhesion properties by use of an underfill material. While a variety of lead-free bumps have been used, those materials which are called copper pillar bumps have been the mainstream in recent years. However, the conventional underfill materials are poor in adhesive strength to copper. This leads to the problem that exfoliation may occur at the interface between the copper bump and the underfill material during solder reflow or temperature cycles, thereby breaking the semiconductor device. In view of this, there is a need for an underfill material free of the problem of exfoliation from the copper bumps.

### SUMMARY OF THE INVENTION

The present invention has been made in consideration of the above-mentioned problems involved in the related art. Accordingly, it is an object of the present invention to provide a liquid epoxy resin composition suitable for use as a non-flow underfill material for semiconductor sealing which has a combination of excellent void properties, solder joint properties, reliability and storage stability, and a flip chip type semiconductor device sealed with the resin composition.

The present inventors made extensive and intensive investigations as to the above-mentioned problems. As a result of their studies, they found out that when a liquid epoxy resin having a specified structure is used jointly with a phenolic curing agent, it is possible to obtain a liquid epoxy resin composition suitable for use as a non-flow underfill material for semiconductor sealing that has a good combination of excellent void properties, solder joint properties, reliability and storage stability.

According to one embodiment of the present invention, there is provided a liquid epoxy resin composition comprising:

(A) a liquid epoxy resin comprising at least one liquid epoxy resin represented by the following general formula (1) or (2):

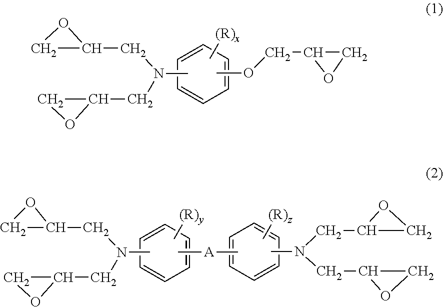

wherein R is independently a halogen atom, an unsubstituted or substituted monovalent hydrocarbon group of 1 to 6 carbon atoms, or an alkoxy group of 1 to 6 carbon atoms, x, y and z are each an integer of 0 to 4, and A is a single bond, an ether group, a thioether group, an SiO₂ group, or an unsubstituted or substituted divalent hydrocarbon group of 1 to 6 carbon atoms,

(B) a phenolic curing agent,

(C) an accelerator in an amount of 0.01 to 10 parts by weight based on 100 parts by weight of component (A), and

(D) an inorganic filler in an amount of 20 to 900 parts by weight based on 100 parts by weight of component (A).

In the liquid epoxy resin composition, the accelerator (C) is preferably an imidazole compound.

The liquid epoxy resin composition may further comprise (F) a fluxing agent added in an amount of 0.1 to 30 parts by weight based on 1.00 parts by weight in total of component (A) and component (B).

In the liquid epoxy resin composition, the fluxing agent (F) is preferably an amino acid or a carboxylic acid.

In the liquid epoxy resin composition, the phenolic curing agent (B) is preferably a phenolic resin having at least two phenolic hydroxyl groups in one molecule.

In the liquid epoxy resin composition, the phenolic curing agent (B) is preferably represented by the following general formula (3):

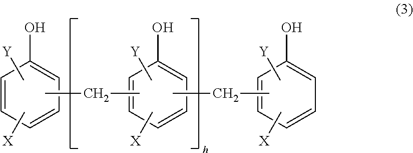

wherein X is independently a hydrogen atom or a monovalent hydrocarbon group of 1 to 6 carbon atoms, Y is independently a hydrogen atom or an allyl group, and h is an integer of 0 to 50.

In the liquid epoxy resin composition, the inorganic filler (D) is preferably selected from the group consisting of fused silica, crystalline silica, alumina, titanium oxide, silica-titania, boron nitride, aluminum nitride, silicon nitride, magnesia, magnesium silicate, aluminum, and mixtures thereof.

The liquid epoxy resin composition may further include (E) a silicone-modified epoxy resin represented by the following, general formula (4):

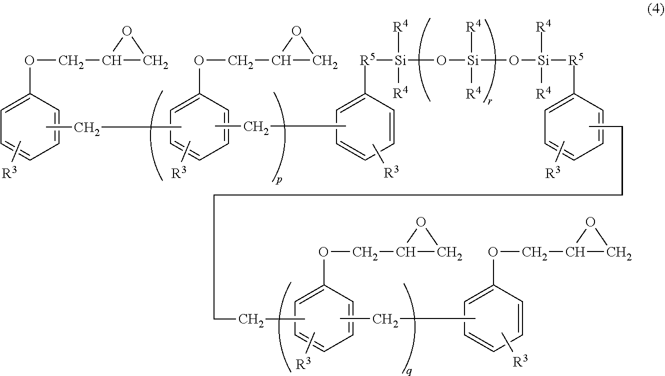

wherein R³ is independently a hydrogen atom or a monovalent hydrocarbon group of 1 to 6 carbon atoms, R⁴ is independently an unsubstituted or substituted monovalent hydrocarbon group, R⁵ is independently —CH₂CH₂CH₂—, —OCH₂—CH(OH)—CH₂—O—CH₂CH₂CH₂—, or —O—CH₂CH₂CH₂—, r is an integer of 8 to 398, p is an integer of 1 to 10, and q is an integer of 1 to 10,

in an amount of 0.1 to 20 parts by weight based on 100 parts by weight in total of component (A) and component (B).

The liquid epoxy resin composition may be for sealing a flip chip semiconductor.

According to one embodiment of the present invention, there is provided a flip chip semiconductor device including a cured product of the above-described liquid epoxy resin composition.

### ADVANTAGEOUS EFFECTS OF THE INVENTION

The liquid epoxy resin composition according to the present invention is excellent in workability, void properties, solder joint properties, adhesion properties and storage stability, and can therefore be suitable for use in manufacture of a flip chip semiconductor device by a non-flow method with high productivity. The liquid epoxy resin composition enables manufacture of a semiconductor device with high reliability.

### BRIEF DESCRIPTION OF THE DRAWINGS

FIG. 1 is a conceptual diagram of a flip chip semiconductor device according to one embodiment of the present invention.

### DESCRIPTION OF THE PREFERRED EMBODIMENTS

The liquid epoxy resin composition according to one embodiment of the present invention contains:

(A) a liquid epoxy resin comprising at least one liquid epoxy resin represented by the following general formula (1) or (2):

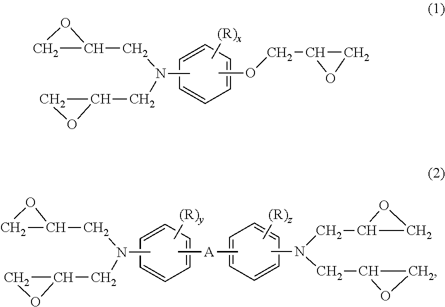

wherein R, which may be identical or different, is a halogen atom, an unsubstituted or substituted monovalent hydrocarbon group of 1 to 6 carbon atoms, or an alkoxy group of 1 to 6 carbon atoms, x, y and z are each an integer of 0 to 4, and A is a single bond (valence bond), an ether group, a thioether group, an SiO₂ group, or an unsubstituted or substituted divalent hydrocarbon group of 1 to 6 carbon atoms,

(B) a phenolic curing agent,

(C) an accelerator, and

(D) an inorganic filler, and

preferably further contains:

(E) a silicone-modified resin, and

(F) a fluxing agent.

Now, the components of the liquid epoxy resin composition will be described individually.

### (A) Liquid Epoxy Resin

The liquid epoxy resin of component (A) used in the present invention includes at least one epoxy resin which is liquid at normal temperature (25° C.) and is represented by the following general formula (1) or (2):

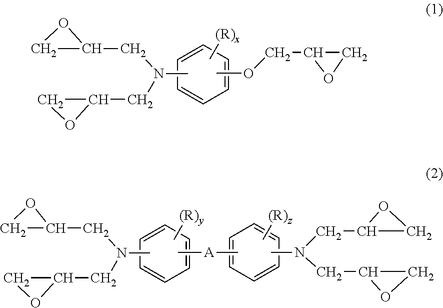

wherein R, which may be identical or different, is a halogen atom such as fluorine, bromine, chlorine, an unsubstituted or substituted monovalent hydrocarbon group of 1 to 6 carbon atoms, or an alkoxy group of 1 to 6 carbon atoms, x, y and z are each an integer of 0 to 4, and A is a single bond, an ether group, a thioether group, an SiO₂ group, or an unsubstituted or substituted divalent hydrocarbon group of 1 to 6 carbon atoms.

The unsubstituted or substituted monovalent hydrocarbon group of R in the above formulas (1) and (2) has 1 to 6 carbon atoms, preferably 1 to 3 carbon atoms. Examples thereof include alkyl groups such as methyl, ethyl, propyl, isopropyl, butyl, isobutyl, tert-butyl, pentyl, neopentyl, and hexyl; cycloalkyl groups such as cyclohexyl; alkenyl groups such as vinyl, allyl, and propenyl; phenyl group; and groups obtained by substituting at least one hydrogen atom in these groups by a halogen atom (e.g., fluorine, bromine, chlorine) or a cyano group, for instance, chloromethyl, chloropropyl, bromoethyl, trifluoropropyl, or cyanoethyl. Besides, examples of the alkoxy groups include those of 1 to 6 carbon atoms, preferably 1 to 3 carbon atoms, such as methoxy, ethoxy, propoxy, and butoxy.

The divalent hydrocarbon group of A in the above formula (2) has 1 to 6 carbon atoms, preferably 1 to 3 carbon atoms. Examples thereof include alkylene groups such as methylene, ethylene, propylene (or trimethylene, or methylethylene), butylenes (or tetramethylene, or methylpropylene), and hexamethylene; and phenylene group. Preferred for use as A are methylene group, ethylene group, and propylene group.

In the above formulas (1) and (2), x, y and z are each an integer of 0 to 4.

The liquid epoxy resins represented by the above formula (1) or (2) may be used either singly or in combination of two or more of them.

As the liquid epoxy resin represented by the above formulas (1) or (2), commercial products can be used. Specific examples of the commercial products include jER630LSD made by Mitsubishi Chemical Corporation, and EP-3900L and EP-3950L made by ADEKA Corporation, for use as liquid epoxy resin of the formula (1), and ELM-434 made by Sumitomo Chemical Co., Ltd. and YH-434L made by Nippon Steel Chemical Co., Ltd., for use as liquid epoxy resin of formula (2).

In the present invention, further, other liquid epoxy resins than the above-mentioned can be jointly used, within such a range as not to spoil the present invention. As the other liquid epoxy resins, those which have been known can be used insofar as they have at least two epoxy groups per molecule and are liquid at normal temperature. Examples of such other liquid epoxy resins include bisphenol A type epoxy resins, bisphenol AD type epoxy resins, bisphenol F type epoxy resins, naphthalene type epoxy resins, phenol-novolak type epoxy resins, biphenyl type epoxy resins, glycidylamine type epoxy resins, alicyclic type epoxy resins, and dicyclopentadiene type epoxy resins. Where the other liquid epoxy resins are used, they can be used either singly or in combination of two or more of them. Among these exemplary other liquid epoxy resins, preferred are bisphenol A type epoxy resins, bisphenol F type epoxy resins, bisphenol AD type epoxy resins, and naphthalene type epoxy resins, which are excellent in heat resistance and moisture resistance.

In the case of using the above-mentioned other liquid epoxy resins, they are preferably used in such a blending ratio that the total amount of the liquid epoxy resins represented by the above formula (1) or (2) is 50 to 100% by weight, particularly 50 to 80% by weight, based on the total amount of component (A).

The total content of chlorine in the liquid epoxy resin(s) of component (A) is desirably up to 1,500 ppm, particularly up to 1,000 ppm. Besides, it is desirable that the amount of chloride ions extracted from water containing 50% by weight of the liquid epoxy resin(s) under the conditions of 100° C.×20 hours be up to 10 ppm. Where the total chlorine content and the amount of chloride ions extracted are up to the above-mentioned upper limits, the liquid epoxy resin composition is good in moisture resistance and would not damage the reliability of semiconductor devices.

(B) Phenolic Curing Agent

Component (B) used in the liquid epoxy resin composition according to the present invention is for curing the liquid epoxy resin of component (A). As a component for curing a liquid epoxy resin, there can be used those compounds which have a functional group capable of reaction with the epoxy groups present in component (A), such as a phenolic hydroxyl group or an amino group. In the present invention, especially, phenolic curing agents are selected from the viewpoint of curing properties. Known phenolic resin curing agents can be used, without any limitations as to molecular structure, molecular weight or the like, insofar as they are compounds which have at least two monovalent groups of phenolic hydroxyl groups or which have at least one substantially divalent group of phenolic hydroxyl group.

Examples of component (B) include phenolic resins having at least two phenolic hydroxyl groups in one molecule. Specific examples include: novolak phenolic resins such as phenol-novolak resin, and cresol-novolak resin; xylylene-modified novolak resins such as paraxylylene-modified novolak resin, metaxylylene-modified novolak resin, and orthoxylylene-modified novolak resin; bisphenol type phenolic resins such as bisphenol A type resin, and bisphenol F type resin; biphenyl type phenolic resin; resol type phenolic resin; phenolaralkyl type resin; biphenylaralkyl type resin; triphenolalkane type resins such as triphenolmethane type resin, and triphenolpropane type resin, and their copolymers; naphthalene ring-containing phenolic resins; dicyclopentadiene-modified phenolic resins; and so on, which may be used either singly or in combination of two or more of them.

Among the above-mentioned phenolic resins, particularly preferred for use are phenolic resins represented by the following general formula (3):

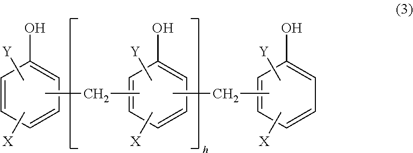

wherein X is independently a hydrogen atom or a monovalent hydrocarbon group of 1 to 6 carbon atoms, Y is independently a hydrogen atom or an allyl group, and h is an integer of 0 to 50, preferably an integer of 0 to 20.

The monovalent hydrocarbon group of X in the above formula (3) has 1 to 6 carbon atoms, preferably 1 to 3 carbon atoms. Examples thereof include alkyl groups such as methyl, ethyl, propyl, isopropyl, butyl, isobutyl, tert-butyl, pentyl, neopentyl, and hexyl; cycloalkyl groups such as cyclohexyl; alkenyl groups such as vinyl, allyl, and propenyl; phenyl group, and groups obtained by substituting at least one hydrogen group in these groups by a halogen atom (e.g., fluorine, bromine, chlorine) or a cyano group, for instance, chloromethyl, chloropropyl, bromoethyl, trifluoropropyl, or cyanoethyl. Among these groups, preferred for use as X are methyl, ethyl, propyl, and allyl groups.

The amount of component (B) to be used is such that the liquid epoxy resin composition in the present invention can be sufficiently cured to a desired extent under normal curing conditions. Thus, the amount of component (B) is not specifically limited, as long as it satisfies the condition that the cured product would not become brittle due to excessive curing and cracks would not be generated upon temperature cycles, and the condition that no curing agent-derived functional groups are left after curing to deteriorate the composition's properties such as sealing property and adhesion property. For instance, the curing agent is preferably used in such an amount that the amount of the functional groups of phenolic hydroxyl groups contained in the curing agent (in the case of a multifunctional group, the amount is calculated by regarding one multifunctional group as a plurality of monovalent groups) is about 0.6 to 1.5 moles, preferably about 0.8 to 1.3 moles, based on 1 mole of the epoxy groups in component (A).

Incidentally, in the case where a silicone-modified resin (a silicone-modified epoxy resin and/or a silicone-modified phenolic resin) of component (E) to be described later is blended into the liquid epoxy resin composition and where the silicone-modified resin has an epoxy group(s), the above-mentioned amount of epoxy groups is replaced by the total amount of the epoxy groups present in component (A) and the epoxy groups present in the silicone-modified resin of component (E). Besides, in the case where the silicone-modified resin of component (E) has a phenolic hydroxyl group(s), the above-mentioned amount of phenolic hydroxyl groups (functional groups) is replaced by the total amount of the functional groups present in component (B) and the phenolic hydroxyl groups present in the silicone-modified resin.

(C) Accelerator

The accelerator (C) to be used in the liquid epoxy resin composition of the present invention is not particularly restricted, as long as it accelerates the curing reaction, and known accelerators can all be used. Examples of the accelerator applicable include imidazole compounds and organic phosphorus compounds. Particularly from the viewpoint of control of curing properties, imidazole compounds are preferred.

Examples of the imidazole compounds include 2-methylimidazole, 2-ethylimidazole, 2-undecylimidazole, 2,4-dimethylimidazole, 2-heptadecylimidazole, 1,2-dimethylimidazole, 1,2-diethylimidazole, 2-phenyl-4-methylimidazole, 2,4,5-triphenylimidazole, 2-ethyl-4-methylimidazole, 2-phenylimidazole, 1-benzyl-2-phenylimidazole, 1-cyanoethyl-2-methylimidazole, 1-cyanoethyl-2-undecylimidazole, 1-benzyl-2-methylimidazole, 2-phenyl-4,5-dihydroxymethylimidazole, 2-allyl-4,5-diphenylimidazole, and 2-phenyl-4-methyl-5-hydroxymethylimidazole.

Among these imidazole compounds, preferred are 2-phenyl-4-methyl-5-hydroxymethylimidazole, 2-phenyl-4,5-dihydroxymethylimidazole, 2-methylimidazole, 2-ethyl-4-methylimidazole, 2-ethylimidazole, 1,2-dimethylimidazole, 1,2-diethylimidazole, 2,4-dimethylimidazole, and 2-phenyl-4-methylimidazole.

Examples of the organic phosphorus compounds include: triorganophosphine compounds such as tributylphosphine, triphenylphosphine, tri(methylphenyl)phosphine, tri(nonylphenyl)phosphine, tri(methoxyphenyl)phosphine, diphenyltolylphosphine, triphenylphosphine-triphenylborane; and quaternary phosphonium salts such as tetraphenylphosphonium tetraphenylborate.

These accelerators may be used either singly or in combination of two or more of them.

The amount of the accelerator blended in the liquid epoxy resin composition is 0.01 to 10 parts by weight, preferably 0.05 to 5 parts by weight, based on 100 parts by weight of the liquid epoxy resin of component (A), from the viewpoint that a cure-accelerating effect is exhibited and that storage stability of the composition would not be damaged thereby.

### (D) Inorganic Filler

The inorganic filler lowers the coefficient of expansion of a cured product. As the filler, conventionally known inorganic fillers can be used. Examples of the usable inorganic fillers include fused silica, crystalline silica, alumina, titanium oxide, silica-titania, boron nitride, aluminum nitride, silicon nitride, magnesia, magnesium silicate, and aluminum, which may be used either singly or in combination of two or more of them. Among these inorganic fillers, preferred is spherical fused silica, from the standpoint of realizing a lowered viscosity of the liquid epoxy resin composition.

From the viewpoint of fluidity and thickening properties, the inorganic filler of component (D) preferably has a weight average diameter D₅₀ (particle diameter at 50% by weight cumulative, or median diameter) upon measurement of particle size distribution by laser diffractometry, for example, of about 0.1 to 20 μm, particularly about 1 to 10 μm.

The inorganic filler is preferably surface treated with a coupling agent such as a silane coupling agent and a titanate coupling agent, prior to use, in order to enhance bonding strength to the resin. Examples of such a coupling agent include epoxysilanes such as γ-glycidoxypropyltrimethoxysilane, γ-glycidoxypropylmethyldiethoxysilane, or β-(3,4-epoxycyclohexyl)ethyltrimethoxysilane, aminosilanes such as N-β(aminoethyl)-γ-aminopropylmethoxysilane, γ-aminopropyltriethoxysilane, or N-phenyl-γ-aminopropyltrimethoxysilane, and mercaptosilanes such as γ-mercaptosilane. The amount of the coupling agent to be used for the surface treatment and the method of surface treatment may be any known amount and any known method.

The amount of the inorganic filler to be blended is 20 to 900 parts by weight, preferably 100 to 500 parts by weight, based on 100 parts by weight of the liquid epoxy resin of component (A). If the amount of the inorganic filler is less than 20 parts by weight, the coefficient of expansion of the cured product of the liquid epoxy resin composition will be so high as to cause cracking of the cured product upon a thermal shock test. If the amount is more than 900 parts by weight, on the other hand, voids are liable to be generated in the cured composition product, and solder joint properties would be lowered by the inorganic filler.

In addition to the above-mentioned components, the liquid epoxy resin composition according to the present invention may further contain the following components, as required, in such ranges as not to impair the effects of the present invention.

### (E) Silicone-Modified Resin

The liquid epoxy resin composition according to the present invention may contain a silicone-modified resin as a stress-lowering agent for lowering the stress on the cured product of the composition. The silicone-modified resin is at least one selected from silicone-modified epoxy resins and silicone-modified phenolic resins, which comprises a copolymer (preferably, a block copolymer) of an organopolysiloxane with an epoxy resin or a phenolic resin. Examples of the stress-lowering agent include silicone resins and thermoplastic resins in powdery form, or rubber-like form, oily form, for instance, liquid polybutadiene rubber or an acrylic core-shell resin. Among such stress-lowering agents, preferred are silicone-modified epoxy resins and silicone-modified phenolic resins. Particularly preferred are silicone-modified epoxy resins or silicone-modified phenolic resins obtained by a known addition reaction of an alkenyl group-containing epoxy resin or alkenyl group-containing phenolic resin represented by any of the following general formula (5) to (8) with an organopolysiloxane which is represented by the following average composition formula (9) and in which the number of silicon atoms in one molecule is 10 to 400 and the number of SiH groups per molecule is 1 to 5.

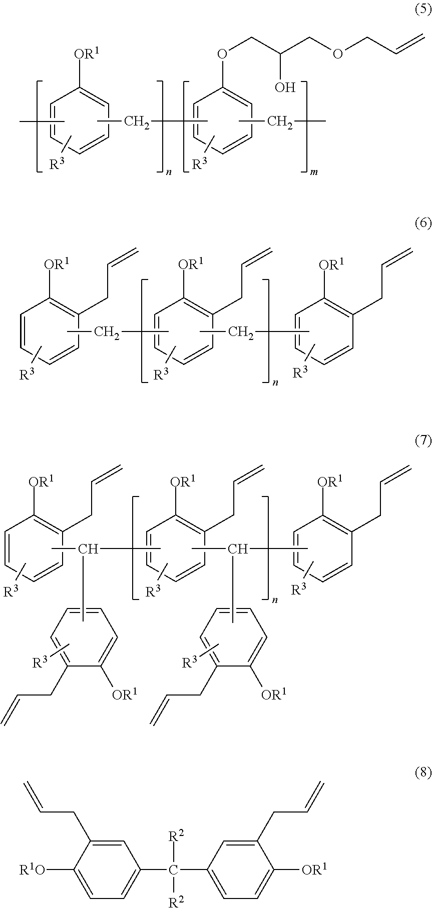

wherein R¹ is independently a hydrogen atom or a glycidyl group represented by the following structure:

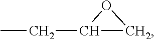

R² is a hydrogen atom or methyl group, R³ is independently a hydrogen atom or a monovalent hydrocarbon group of 1 to 6 carbon atoms, n is an integer of 0 to 50, preferably 1 to 20, and m is an integer of 1 to 5, preferably 1.

HₐR⁴_{b}SiO_{(4-a-b)/2} (9)

wherein R⁴ is independently an unsubstituted or substituted monovalent hydrocarbon group, a is 0.01 to 0.1, and b is 1.8 to 2.2, provided that 1.81≦a+b≦2.3.

Examples of the monovalent hydrocarbon group of 1 to 6 carbon atoms, preferably 1 to 3 carbon atoms, of R³ in the above formulas (5) to (7) include alkyl groups such as methyl, ethyl, propyl, isopropyl, butyl, tert-butyl, pentyl, and hexyl; cycloalkyl groups such as cyclopentyl, and cyclohexyl; aryl groups such as phenyl; and alkenyl groups such as vinyl, and allyl. The R³ groups may be identical or different.

The monovalent hydrocarbon groups of R⁴ in the above formula (9) are preferably those of 1 to 10 carbon atoms, particularly 1 to 8 carbon atoms. Examples of such monovalent hydrocarbon groups include alkyl groups such as methyl, ethyl, propyl, isopropyl, butyl, isobutyl, tert-butyl, hexyl, octyl, and decyl; alkenyl groups such as vinyl, allyl, propenyl, butenyl, and hexenyl; aryl groups such as phenyl, xylyl, and tolyl; aralkyl groups such as benzyl, phenylethyl, and phenylpropyl; and halogen-substituted monovalent hydrocarbon groups obtained by substituting part or all of the hydrogen atoms in these hydrocarbon groups by a halogen atom (e.g., chlorine, fluorine, bromine), such as fluoromethyl, bromoethyl, and trifluoropropyl.

Among the above-mentioned silicone-modified resins, the most preferable silicone-modified epoxy resins are those represented by the following general formula (4):

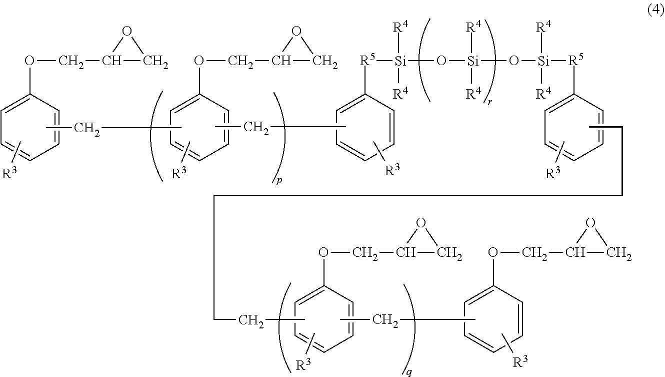

In the above formula, R³ and R⁴ are the same as defined above, and R⁵ is —CH₂CH₂CH₂—, —OCH₂—CH(OH)—CH₂—O—CH₂CH₂CH₂—, or —O—CH₂CH₂CH₂—; r is an integer of 8 to 398, preferably 18 to 198; p is an integer of 1 to 10; and q is an integer of 1 to 10.

Examples of R³ and R⁴ in the above formula include the same groups as defined above, among which methyl group is preferred as R³, and methyl group is preferred as R⁴, as well. R³ may be identical or different, and R⁴ may also be identical or different.

In the above formula, p and q are each an integer of 1 to 10, preferably 1 to 5. If p and/or q is more than 10, the cured product of the composition would be so hard as to lead to deteriorated cracking resistance or deteriorated adhesion, thereby considerably spoiling reliability of the resin.

In the above formula, r is an integer of 8 to 398, preferably 18 to 198. If r is less than 8, the proportion of the polysiloxane moiety for relaxing stress becomes so low that a sufficient stress-lowering effect cannot be obtained. If r is more than 398, on the other hand, dispersibility of the resin would be lowered, leading to easy separation, resin quality would be instable, and a sufficient stress-lowering effect cannot be obtained.

In the case of blending component (E) into the liquid epoxy resin composition of the present invention, the amount of component (E) is 0.1 to 20 parts by weight, preferably 1 to 20 parts by weight, more preferably 2 to 15 parts by weight, based on 100 parts by weight in total of the liquid epoxy resin of component (A) and the phenolic curing agent of component (B). Where the amount of the component (E) is within this range, a further lowering in stress can be achieved.

### (F) Fluxing Agent

The liquid epoxy resin composition of the present invention may contain a fluxing agent in such a range as not to spoil the void property improving effect in the invention.

In the present invention, the fluxing agent is used to supplementing the fluxing capacity possessed by the curing agent. In general, many of the above-mentioned curing agents have a fluxing capability, as well. The type and amount of the fluxing agent to be used are appropriately controlled, according to the type of the curing agent used and its fluxing capacity.

The fluxing agent for use in the present invention is not specifically restricted, insofar as it has a reducing ability. Examples of the usable fluxing agent include hydrazides, amino acids, carboxylic acids (exclusive of amino acids), phenols, reducing sugars, sulfides, and thioether phenols. Among these, preferred are amino acids and carboxylic acids.

Specific examples of the fluxing agent include the following.

Examples of the hydrazides include 3-bis(hydrazinocarbonoethyl)-5-isopropylhydantoin or 7,11-octadecadiene-1,18-dicarbohydrazide, adipic dihydrazide, sebacic dihydrazide, dodecanediohydrazide, isophthalic dihydrazide, propionic hydrazide, salicylic hydrazide, 3-hydroxy-2-naphthoeic hydrazide, and benzophenonehydrazone.

Examples of the amino acids include isoleucine, glycine, alanine, serine, lysine, proline, arginine, aspartic acid, glutamine, glutamic acid, and aminobenzoic acid.

Examples of the carboxylic acids (organic acids) include: aliphatic monocarboxylic acids such as caproic acid, enanthic acid, caprylic acid, capric acid, undecanoic acid, tridecanoic acid, myristic acid, pentadecanoic acid, palmitic acid, heptadecanoic acid, nonadecanoic acid, arachidic acid, isocaprylic acid, propylvaleic acid, ethylcaproic acid, isocaprylic acid, 2,2-dimethylbutanoic acid, 2,2-dimethylpentanoic acid, 2,2-dimethylhexanoic acid, 2,2-dimethyloctanoic acid, 2-methyl-2-ethylbutanoic acid, 2-methyl-2-ethylpentanoic acid, 2-methyl-2-ethylhexanoic acid, 2-methyl-2-ethylheptanoic acid, 2-methyl-2-propylpentanoic acid, 2-methyl-2-propylhexanoic acid, 2-methyl-2-propylheptanoic acid, octylic acid, octenoic acid, oleic acid, cyclopentanecarboxylic acid, and cyclohexanecarboxylic acid; aliphatic polycarboxylic acids such as oxalic acid, malonic acid, succinic acid, glutaric acid, adipic acid, pimelic acid, suberic acid, azelaic acid, sebacic acid, methylmalonic acid, ethylmalonic acid, methylsuccinic acid, ethylsuccinic acid, 2,2-dimethylsuccinic acid, 2,3-dimethylsuccinic acid, 2-methylglutaric acid, 3-methylglutaric acid, maleic acid, citraconic acid, itaconic acid, methyleneglutaric acid, monomethyl maleate, 1,5-octanedicarboxylic acid, 5,6-decanedicarboxylic acid, 1,7-decanedicarboxylic acid, 4,6-dimethyl-4-nonene-1,2-dicarboxylic acid, 4,6-dimethyl-1,2-nonanedicarboxylic acid, 1,7-dodecanedicarboxylic acid, 5-ethyl-1,10-decanedicarboxylic acid, 6-methyl-6-dodecne-1,12-dicarboxylic acid, 6-methyl-1,12-dodecanedicarboxylic acid, 6-ethylene-1,12-dodecanedicarboxylic acid, 6-ethyl-1,12-dodecanedicarboxylic acid, 7-methyl-7-tetradecene-1,14-dicarboxylic acid, 7-methyl-1,14-tetradecanedicarboxylic acid, 3-hexyl-4-decene-1,2-dicarboxylic actd, 3-hexyl-1,2-decanedicarboxylic acid, 6-ethylene-9-hexadecene-1,16-dicarboxylic acid, 6-ethyl-1,16-hexadecanedicarboxylic acid, 6-phenyl-1,12-dodecanedicarboxylic acid, 7,12-dimethyl-7,11-octadecadiene-1,18-dicarboxylic acid, 7,12-dimethyl-1,18-octadecanedicarboxylic acid, 6,8-diphenyl-1,14-tetradecanedicarboxylic acid, 1,1-cyclopentanedicarboxylic acid, 1,2-cyclopentanedicarboxylic acid, 1,1-cyclohexenedicarboxylic acid, 1,2-cyclohexenedicarboxylic acid, 4-cyclohexene-1,2-dicarboxylic acid, 5-norbornene-2,3-dicarboxylic acid, and malic acid; aromatic monocarboxylic acids such as benzoic acid, toluic acid, ethylbenzoic acid, propylbenzoic acid, isopropylbenzoic acid, butylbenzoic acid, isobutylbenzoic acid, hydroxybenzoic acid, anisic acid, ethoxybenzoic acid, propoxybenzoic acid, isopropoxybenzoic acid, butoxybenzoic acid, isobutoxybenzoic acid, nitrobenzoic acid, and resorcinbenzoic acid; aromatic polycarboxylic acids such as phthalic acid, nitrophthalic acid, and trimellitic acid; and resin acids such as abietic acid, palustric acid, levopimaric acid, and dehydroabietic acid.

Examples of the phenols include β-naphthol, o-nitrophenol, p-nitrophenol, catechol, resorcin, 4,4′-dihydroxydiphenyl-2,2-propane, phenol-novolak, and cresol-novolak.

Examples of the reducing sugars include glucose, fructose, galactose, psicose, mannose, allose, tagatose, ribose, deoxyribose, xylose, arabinose, maltose, and lactose.

Examples of the sulfides include allyl propyl trisulfide, benzyl methyl disulfide, bis-(2-methyl-3-furyl)disulfide, dibenzyl disulfide, dicyclohexyl disulfide, difurfuryl disulfide, diisopropyl disulfide, 3,5-dimethyl-1,2,4-trithiolane, di-o-tolyl disulfide, dithienyl disulfide, methyl 2-methyl-3-furyl disulfide, methyl 2-oxopropyl disulfide, methyl 5-methylfurfuryl disulfide, methyl o-tolyl disulfide, methyl phenyl disulfide, methyl propyl trisulfide, 3-methylthiobutanal, 4-methylthiobutanal, 2-methylthiobutanal, phenyldisulfide, 4,7,7-trimethyl-6-thiabicyclo[3.2.1]octane, 2,3,5-trithiohexane, 1,2,4-trithiolane, 2-(furfurylthio)-3-methylpyrazine, 2-(methylthio)benzothiazole, 2,8-epi-thio-p-menthane, 2-isopropyl-3-(methylthio)pyrazine, 2-methyl-1,3-dithiolane, 2-(methylthio)acetaldehyde, 2-methylthiolane, 2-methylthiothiazole, 3,5-diethyl-1,2,4-trithiolane, bis(2-methylbutyl)disulfide, diallyl trisulfide, dibutyl disulfide, diisobutyl disulfide, dipentyl disulfide, and di-sec-butyl disulfide.

Examples of the thioether phenols include 2,2-thiodiethylene bis[3-(3,5-di-t-butyl-4-hydroxyphenyl)-propionate], 2,4-bis[(octylthio)methyl]-o-cresol, and 4,4-thiobis-(2-t-butyl-5-methylphenol).

The fluxing agent used in the present invention should be optimized in relation to the curing agent used, taking into account the storage stability of the liquid epoxy resin composition and the fluxing ability retention in the solder joining temperature region. In addition, in order not to become a source of voids, it is necessary for the fluxing agent not to be evaporated or boiled in the solder joining temperature region.

It is desirable that the amount of the fluxing agent is up to 30 parts by weight, preferably 0.1 to 30 parts by weight, more preferably 1 to 20 parts by weight, based on 100 parts by weight in total of the liquid epoxy region (A) and the phenolic curing agent (B). If the amount of the fluxing agent exceeds 30 parts by weight, the glass transition temperature of the resin composition may be lowered, thereby lowering heat resistance and/or adhesion properties.

In preparing the liquid epoxy resin composition of the present invention, the fluxing agent may be blended as it is where the fluxing agent is liquid. Where the fluxing agent is solid, it may be blended into the composition in a solid state after pulverization. Depending on the amount of the fluxing agent used, however, the solid fluxing agent may greatly increase the viscosity of the resin, leading to a markedly lowered workability. It is preferable, therefore, to preliminarily put the solid fluxing agent to melt mixing with the liquid epoxy resin or a liquid curing agent. In the case of putting the solid fluxing agent to melt mixing with the liquid epoxy resin or the liquid curing agent, the melt mixing is preferably conducted in a temperature range of 70 to 150° C. for one to two hours.

### Other Additives

The liquid epoxy resin composition according to the present invention may be admixed with surface active agents, antifoaming agents, leveling agents, ion trapping agents, pigments (e.g., carbon black), dyes or other additives, as required, in such ranges as not to spoil the purpose of the present invention.

The liquid epoxy resin composition of the present invention can be obtained by mixing (A) the liquid epoxy resin, (B) the phenolic curing agent, (C) the accelerator, (D) the inorganic filler, and the optional components, either simultaneously or separately, and while heating if necessary. The mixing apparatus to be used is not particularly restricted; for example, a chaser mill, a three-roll mill, a ball mill, a planetary mixer or the like, provided with stirring and heating devices, can be used. Besides, an appropriate combination of these apparatuses may also be used.

Incidentally, the viscosity of the liquid epoxy resin composition of the present invention, as measured by a rotational viscometer (e.g., BL type, BH type, BS type, cone-and-plate type, etc.), is preferably up to 1,000 Pa·s (0.1 to 1,000 Pa·s), particularly up to 500 Pa·s (1 to 500 Pa·s), at 25° C.

As for the molding method and molding conditions for the liquid epoxy resin composition, it is preferable to first heat the composition at 90 to 120° C. for about 0.5 hour and thereafter put the composition to heat cure at 150 to 175° C. for about 0.5 to four hours. The first heating makes it possible to securely prevent generation of voids upon curing. If the period of the heating at 150 to 175° C. is less than 0.5 hour, the cured product may fail to show satisfactory properties.

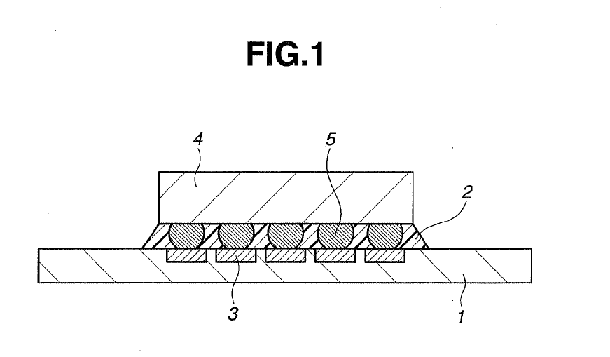

The liquid epoxy resin composition according to the present invention can be suitably used as a sealant for flip chip semiconductor devices. The flip chip semiconductor device for use in the present invention is, for example, as shown in FIG. 1. Ordinarily, the flip chip semiconductor device has a configuration wherein a semiconductor chip 4 is mounted on a wiring pattern side of an organic (electronic circuit) substrate 1, with a plurality of solder bumps 5 therebetween, and with the gap between the organic substrate 1 and the semiconductor chip 4 and the gaps between the solder bumps 5 being filled with an underfill material 2. In FIG. 1, numeral 3 denotes a pad. The liquid epoxy resin composition of the present invention is particularly effective when used as the underfill material.

Where the liquid epoxy resin composition according to the present invention is used as an underfill material, the coefficient of expansion of the cured composition product below its glass transition temperature is preferably 20 to 40 ppm/° C.

### EXAMPLES

Now, the present invention will be specifically described below based on Examples and Comparative Examples, which are not intended to restrict the invention. Besides, in the following description, % and parts are % by weight and parts by weight, unless otherwise specified.

### Examples 1 to 3, and Comparative Examples 1 to 4

A liquid epoxy resin, a curing agent, an inorganic filler, a fluxing agent, an accelerator, and a silicone-modified epoxy resin were mixed in formulations as set forth in Table 1 below, and were uniformly kneaded by a planetary mixer. Next, the solid raw materials were sufficiently mixed and dispersed by a three-roll mill, and the resulting mixture was subjected to a vacuum degassing treatment. In this manner, liquid epoxy resin compositions were obtained. Incidentally, L-glutamine as the fluxing agent was used as it was in particulate solid form, whereas abietic acid as the fluxing agent was preliminarily put to melt mixing with the liquid epoxy resin, before being mixed with the other ingredients.

The formulations of the liquid epoxy resin compositions in Examples and Comparative Examples are set forth in Table 1. The numerical values in Table 1 are amounts in parts by weight.

TABLE 1

| | | | | | Comparative | | | |
|---|---|---|---|---|---|---|---|---|
| Liquid epoxy resin composition, | | Example | | | Example | | | |
| Amount (parts by weight) | | 1 | 2 | 3 | 1 | 2 | 3 | 4 |
| Liquid epoxy resin | jE630LSD | 40 | 40 | 20 | | | 20 | 20 |
| | Epotohto ZX1059 | | | 20 | 50 | 45 | 20 | 20 |
| Curing agent | MEH-8005 | 60 | 35 | 50 | 45 | | | |
| | Resitop PL6328 | | 20 | | | | | |
| | BPA-CA | | | | | 45 | | |
| | Kayahard A-A | | | | | | 22 | 22 |
| Inorganic filler | Spherical silica | 100 | 100 | 100 | 100 | 100 | 100 | 100 |
| Fluxing agent | L-Glutamine | 4 | 4 | | 4 | 4 | 4 | |
| | Abietic acid | | | 5 | | | | 4 |
| Accelerator | 2PHZ-PW | 0.1 | 0.1 | 0.1 | 0.1 | 0.1 | 0.1 | 0.1 |

| | | | | | | | |
|---|---|---|---|---|---|---|---|
| Silicone-modified epoxy resin | 5 | 5 | 10 | 10 | 10 | 5 | 5 |

(A) Liquid epoxy resin
jER630LSD (N,N-bis(2,3-epoxypropy1)-4-(2,3-epoxypropoxy)-aniline; made by Mitsubishi Chemical Corporation; epoxy equivalent: 92)
Epotohto ZX1059 (a mixture of bisphenol A type epoxy resin with bisphenol F type epoxy resin; made by Tohto Kasei Co., Ltd.; epoxy equivalent: 166)
(B) Curing agent
Phenolic curing agent:
MEH-8005 (an allylphenol-formaldehyde resin; made by Meiwa Plastic Industries, Ltd.; equivalent: 135)
Resitop PL6328 (a phenol-novolak resin; made by Gun Ei Chemical Industry Co., Ltd.; equivalent: 110)
BPA-CA (diallylbisphenol A; made by Konishi Chemical Ind. Co., Ltd.; equivalent: 154)
Amine curing agent:
Kayahard A-A (made by Nihon Kayaku Co., Ltd.; equivalent: 63.5)
(C) Accelerator
Imidazole accelerator:
2PHZ-PW (made by Shikoku Chemicals Corporation)
(D) Inorganic filler
Spherical silica: average particle diameter 2 μm; maximum particle diameter 10 μm (made by Admatechs Co., Ltd.)
(E) Silicone-modified epoxy resin
Silicone-modified epoxy resin:
Addition polymer of a compound of the following formula (10) with a compound of the following formula (11) (weight average molecular weight 3,800; epoxy equivalent: 291) 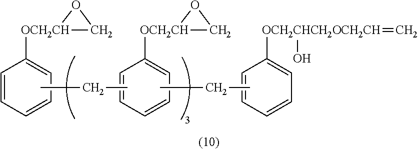 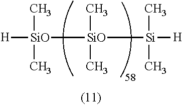
(F) Fluxing agent
Amino acid: L-glutamine
Carboxylic acid: abietic acid

The liquid epoxy resin compositions of Examples and Comparative Examples were put to characteristics evaluation as to the following items. The evaluation results are set forth in Table 2 below.

### (1) Viscosity

Viscosity at 25° C. was measured by use of a BROOKFIELD cone/plate viscometer (HBDV-III) at a rotating speed of 1.0 rpm.

### (2) Preservability

Each of the liquid epoxy resin compositions was preserved in an environment of 25° C. and 60% RH. Based on the viscosity change rate (the ratio of the viscosity after leaving to stand for 48 hours to the initial viscosity), pot life was evaluated according to the following criteria. Incidentally, viscosity measurement was carried out under the above-mentioned conditions.
◯: The change rate relative to initial viscosity is less than 30%, showing good pot life.
Δ: The change rate relative to initial viscosity is 30 to 100%, showing some problem as to pot life.
×: The change rate relative to initial viscosity is in excess of 100%, indicating a short and unsatisfactory pot life.

### (3) Adhesion to Cu

A Si chip measuring 2 mm by 2 mm was coated with 0.4 mg of the liquid epoxy resin composition, and the assembly was adhered to a Cu plate measuring 18 mm by 18 mm. Thereafter, the resin composition was cured by heating at 120° C. for 0.5 hour and at 165° C. for three hours. The specimens obtained in this manner were put to measurement of adhesive strength under shear between the resin layer and the Cu plate at 260° C. by use of a bond tester (made by DAGE, England).

### (4) Solder Point Properties

A flip chip mounting evaluation TEG (made by TEG Service Co., Ltd.; bump: Sn-3.0Ag-0.5Cu, diameter 80 μm/height 50 μm/pitch 150 μm) was used. The liquid epoxy resin composition was applied to a substrate by use of a dispenser. Then, using a flip chip bonder FCB3 (made by Panasonic Factory Solutions Co., Ltd.), the semiconductor chip was mounted (contact temperature: 100° C.; solder joint: temperature 260° C., load 20 N), and the resin composition was cured by heating at 100° C. for 0.5 hour and at 150° C. for four hours, to fabricate a flip chip semiconductor specimen. For each of the resin compositions, ten specimens (40 areas in total) were prepared. The presence or absence of conduction was checked for each area, and solder joint properties were evaluated according to the following criteria.
◯: Conduction is present in all areas
Δ: Conduction is present in some areas
×: Conduction is absent in all areas

### (5) Void Properties

For each of the flip chip semiconductor specimens prepared for evaluation of solder joint properties above, the chip status of void generation in the resin was observed using an ultrasonic flaw detector QUANTUM-350 (made by Sonix Corporation). The void generation status was evaluated according to the following criteria.
◯: Nearly voidless
Δ: Voids found scattered throughout the surface
×: Innumerable voids generated throughout the surface

### (6) Exfoliation Test

Five void-free chips of the flip chip semiconductor specimens in each of Examples and Comparative Examples (exclusive of Comparative Examples 1 and 2) were left to stand in an atmosphere of 30° C. and 65% RH for 192 hours, and subjected to IR reflow at a maximum temperature of 265° C. Thereafter, the number of chips showing generation of cracks or exfoliation was checked using the ultrasonic flaw detector. Further, the chips were placed in an environment of PCT (pressure cooker test) (121° C., 2.1 atm) for 336 hours, whereon the number of chips showing generation of cracks or exfoliation was checked using the ultrasonic flaw detector.

### (7) Temperature Cycle Test

Five void-free chips of the flip chip semiconductor specimens in each of Examples and Comparative Examples (exclusive of Comparative Examples 1 and 2) were left to stand in an atmosphere of 30° C. and 65% RH for 192 hours, and thereafter subjected to temperature cycles. Each of the temperature cycles consisted of keeping the chips at −65° C. for 30 minutes and then keeping the chips at 150° C. for 30 minutes. After 500 cycles and after 1,000 cycles, the number of chips showing generation of cracks or exfoliation was checked.

The results of measurements and tests are set forth in Table 2 below. For Comparative Examples 1 and 2, the exfoliation test and the temperature cycle test were not conducted because no void-free specimen was obtained.

TABLE 2

| | | | | | Comparative | | | |
|---|---|---|---|---|---|---|---|---|
| | | Example | | | Example | | | |
| | | 1 | 2 | 3 | 1 | 2 | 3 | 4 |
| Viscosity | Pa · s (25° C.) | 80 | 200 | 180 | 150 | 80 | 60 | 60 |
| Preservability | | ◯ | ◯ | ◯ | Δ | ◯ | ◯ | X |
| Adhesion to Cu | MPa (260° C.) | 10 | 11 | 12 | 12 | 11 | 0 | 0 |
| Solder joint properties | | ◯ | ◯ | ◯ | X | Δ | ◯ | Δ |
| Void properties | Status | ◯ | ◯ | ◯ | Δ | X | ◯ | ◯ |
| Exfoliation test | IR 265° C. × 5 | 0/5 | 0/5 | 0/5 | — | — | 0/5 | 0/5 |
| | PCT 336 hr | 0/5 | 0/5 | 0/5 | — | — | 0/5 | 0/5 |
| Temperature | 500 cycles | 0/5 | 0/5 | 0/5 | — | — | 0/5 | 0/5 |
| cycle test | 1,000 cycles | 0/5 | 0/5 | 0/5 | — | — | 0/5 | 0/5 |

As is clear from Table 2, the epoxy resin compositions prepared in Examples were excellent in preservability and solder joint properties, and were excellent in reliability because void generation was restrained remarkably. On the other hand, the epoxy resin compositions obtained in Comparative Examples 1 and 2 showed generation of many voids, and were therefore poor in void properties. The epoxy resin compositions of Comparative Examples 3 and 4 were poor in adhesion to Cu plate, and the specimens of Comparative Examples 2 and 4 partly showed joint failure. Further, the epoxy resin composition of Comparative Example 1 showed too high a curing rate, and was poor in solder joint properties. In addition, the epoxy resin composition of Comparative Example 4 was poor in preservability.

Although some preferred embodiments have been described, many modifications and variations may be made thereto in light of the above teachings. It is therefore to be understood that the invention may be practiced otherwise than as specifically described without departing from the scope of the appended claims.

Japanese Patent Application No. 2012-019421 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A liquid epoxy resin composition comprising:
(A) a liquid epoxy resin comprising at least one liquid epoxy resin represented by the following general formula (1) or (2): 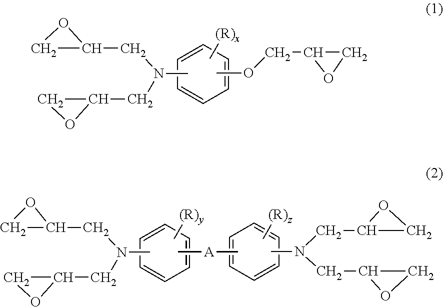
wherein R is independently a halogen atom, an unsubstituted or substituted monovalent hydrocarbon group of 1 to 6 carbon atoms, or an alkoxy group of 1 to 6 carbon atoms, x, y and z are each an integer of 0 to 4, and A is a single bond, an ether group, a thioether group, an SiO₂ group, or an unsubstituted or substituted divalent hydrocarbon group of 1 to 6 carbon atoms,
(B) a phenolic curing agent,
(C) an accelerator in an amount of 0.01 to 10 parts by weight based on 100 parts by weight of component (A), and
(D) an inorganic filler in an amount of 20 to 900 parts by weight based on 100 parts by weight of component (A).

2. The liquid epoxy resin composition according to claim 1, wherein the accelerator (C) is an imidazole compound.

3. The liquid epoxy resin composition according to claim 1, further comprising (F) a fluxing agent added in an amount of 0.1 to 30 parts by weight based on 100 parts by weight in total of component (A) and component (B).

4. The liquid epoxy resin composition according to claim 3, wherein the fluxing agent (F) is an amino acid or a carboxylic acid.

5. The liquid epoxy resin composition according to claim 1, wherein the phenolic curing agent (B) is a phenolic resin having at least two phenolic hydroxyl groups in one molecule.

6. The liquid epoxy resin composition according to claim 5, wherein the phenolic curing agent (B) is represented by the following general formula (3): 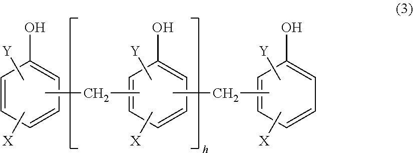
wherein X is independently a hydrogen atom or a monovalent hydrocarbon group of 1 to 6 carbon atoms, Y is independently a hydrogen atom or an allyl group, and h is an integer of 0 to 50.

7. The liquid epoxy resin composition according to claim 1, wherein the inorganic filler (D) is selected from the group consisting of fused silica, crystalline silica, alumina, titanium oxide, silica-titania, boron nitride, aluminum nitride, silicon nitride, magnesia, magnesium silicate, aluminum, and mixtures thereof.

8. The liquid epoxy resin composition according to claim 1, further comprising (E) a silicone-modified epoxy resin represented by the following general formula (4): 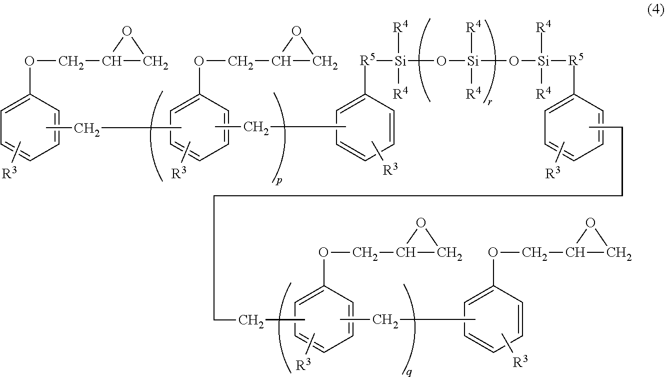
wherein R³ is independently a hydrogen atom or a monovalent hydrocarbon group of 1 to 6 carbon atoms, R⁴ is independently an unsubstituted or substituted monovalent hydrocarbon group, R⁵ is independently —CH₂CH₂CH₂—, —OCH₂—CH(OH)—CH₂—O—CH₂CH₂CH₂—, or —O—CH₂CH₂CH₂—, r is an integer of 8 to 398, p is an integer of 1 to 10, and q is an integer of 1 to 10,
in an amount of 0.1 to 20 parts by weight based on 100 parts by weight in total of component (A) and component (B).

9. The liquid epoxy resin composition according to claim 1, which is for sealing a flip chip semiconductor.

10. A flip chip semiconductor device comprising a cured product of the liquid epoxy resin composition of claim 9.
